(19) United States
(12) Patent Application Publication
(10) Pub. No.: US 2026/0215259 A1
(43) Pub. Date: Jul. 23, 2026

(54) SEMICONDUCTOR DEVICE

(71) Applicant: WAVEPIA CO., LTD., Hwaseong-si (KR)

(72) Inventors: Sang Hun LEE, Hwaseong-si (KR); Sang Yeol LEE, Hwaseong-si (KR)

(73) Assignee: WAVEPIA CO., LTD., Hwaseong-si (KR)

(21) Appl. No.: 19/345,873

(22) Filed: Sep. 30, 2025

(30) Foreign Application Priority Data
Jan. 22, 2025 (KR) 10-2025-0009638

(51) Int. Cl. H10W 40/00; H10D 30/47; H10D 62/85; H10W 20/41

(52) U.S. Cl. CPC H10W 40/00; H10D 30/475; H10D 62/8503; H10W 20/427

(57) ABSTRACT

The present invention relates to a semiconductor device. The semiconductor device of the present invention includes a ground layer, a semiconductor substrate disposed on the ground layer, a semiconductor layer disposed on the semiconductor substrate, one or more first resistors disposed in the semiconductor layer, one or more first temperature measurement pads disposed on the semiconductor layer, one or more transistors disposed on the semiconductor layer, and a plurality of heat-insulating walls passing through the semiconductor layer, wherein each of the one or more transistors includes a gate electrode, a source electrode, a drain electrode, and a channel region located between the source electrode and the drain electrode in the semiconductor layer, and may block mutual heating between the channel regions through the heat-insulating walls.

### CROSS-REFERENCE TO RELATED APPLICATION

This application claims priority to and the benefit of Korean Patent Application No. 10- 2025-0009638, filed on January 22, 2025, the disclosure of which is incorporated herein by reference in its entirety.

### BACKGROUND

### 1. Field of the Invention

The present invention relates to a semiconductor device, and more particularly, to a semiconductor device including a resistor disposed in a semiconductor layer.

### 2. Discussion of Related Art

Recently, with the advancement of technologies in fields such as electric vehicles, autonomous vehicles, wireless communication including 5G and 6G, satellite communication, and high-resolution radar, semiconductor devices used in these fields are increasingly required to enable high-frequency signal processing, high-speed operation, and high output. As the operating speed and output of the semiconductor device increase, transistors disposed in the semiconductor device switch at higher speeds, and larger currents flow through channel regions of the transistors. In this process, the power consumption of the semiconductor device increases, and at the same time, the amount of heat generated by the semiconductor device also increases.

When the amount of heat generated by the semiconductor device increases, various parts constituting the semiconductor device may undergo degradation due to stress resulting from excessive temperature variations. For example, cracks may occur in each layer constituting the semiconductor device, the lifespan of semiconductor elements may be

shortened, or switching performance may deteriorate due to a decrease in electron mobility.

Accordingly, heat sink structures and cooling systems have been proposed to effectively dissipate heat of the semiconductor device. However, as the switching speed of the semiconductor device increases or the size of the semiconductor device becomes smaller, the efficiency of the conventional heat sink structures and cooling systems in dissipating heat generated in the semiconductor device may decrease. In addition, various temperature measurement methods have been attempted in semiconductor devices to check the state of heat generation, but there has been a problem in that it is difficult to measure the exact temperature, such as when the temperature of air already heated by the semiconductor device is measured. That is, in recent semiconductor devices, there has been a problem in that it is not possible to accurately measure the location where heat generation is concentrated and the extent of heat generation. Thus, conventional heat measurement devices and heat dissipation devices for semiconductor devices fail to promptly measure heat generated by an actual heat source of the semiconductor device or to respond quickly to heat generation, resulting in performance degradation and reduced lifespan of semiconductor elements as usage time increases.

Accordingly, there is a need for technology to address the above-described issues. Meanwhile, the above-described background art is technical information possessed by the inventor for derivation of the present invention or acquired by the inventor during the derivation of the present invention, and is not necessarily considered to be a known technology open to the general public prior to the filing of the present invention.

### Prior-Art Document

### Patent Document

Patent Document 1 Korean Unexamined Patent Publication No. 10-2009-0074548 (July 7, 2009)

### SUMMARY OF THE INVENTION

The present invention is directed to providing a semiconductor device capable of accurately measuring a degree of heat generation of a highest heat-generating source of the semiconductor device by calculating a temperature through a resistor disposed in a semiconductor layer.

The present invention is also directed to providing a semiconductor device capable of accurately measuring a temperature of a target semiconductor element and a target heat- generating point by including a heat-insulating wall passing through a semiconductor layer.

The present invention is also directed to providing a semiconductor device capable of more accurately measuring a temperature of a semiconductor layer inside the semiconductor device by covering upper portions of a plurality of resistors with a temperature measurement pad and an insulator.

The present invention is also directed to providing a semiconductor device capable of more accurately calculating a temperature of a semiconductor layer by allowing at least one resistor to receive heat of the semiconductor layer through a via connected to the semiconductor layer.

The present invention is also directed to providing a semiconductor device capable of blocking external influences from affecting a temperature of a target heat-generating point for temperature measurement by spacing apart a plurality of ground pads that receive heat of a semiconductor layer from each other in a region in which a heat-insulating wall is disposed.

Objectives of the present invention are not limited to the above-described objectives, and other objectives that are not described herein will be apparently understood by those skilled in the art from the following description.

According to an aspect of the present invention, there is provided a semiconductor device including a ground layer, a semiconductor substrate disposed on the ground layer, a semiconductor layer disposed on the semiconductor substrate, one or more first resistors disposed in the semiconductor layer, one or more first temperature measurement pads disposed on the semiconductor layer, one or more transistors disposed on the semiconductor layer, and a plurality of heat-insulating walls passing through the semiconductor layer, wherein each of the one or more transistors includes a gate electrode, a source electrode, a drain electrode, and a channel region located between the source electrode and the drain electrode in the semiconductor layer.

According to another aspect of the present invention, the plurality of heat-insulating walls may be disposed on both sides of the channel region to be spaced apart from the channel region.

According to another aspect of the present invention, the one or more first resistors may be disposed between the plurality of heat-insulating walls.

According to another aspect of the present invention, the one or more first temperature measurement pads may be disposed on the one or more first resistors.

According to another aspect of the present invention, the semiconductor device may further include an insulating layer disposed on the one or more first resistors, wherein the insulating layer and the one or more first temperature measurement pads may cover entire upper surfaces of the one or more first resistors.

According to another aspect of the present invention, the semiconductor device may further include an insulating layer disposed between the semiconductor layer and each of the source electrode and the drain electrode, wherein the heat-insulating walls may be disposed below the insulating layer.

According to another aspect of the present invention, the plurality of heat-insulating walls may be disposed to pass through between an upper surface of the semiconductor layer and a lower surface of the semiconductor substrate.

According to another aspect of the present invention, the ground layer may include a plurality of ground patterns, and the plurality of ground patterns may be spaced apart from each other in regions in which the plurality of heat-insulating walls are disposed.

According to another aspect of the present invention, the semiconductor device may further include a first via disposed between the ground layer and each of the one or more first resistors, and a second via disposed between the source electrode and the ground layer, wherein the second via may have thermal conductivity and electrical conductivity, and may be electrically connected to the source electrode and the ground layer.

According to another aspect of the present invention, the first via may have thermal conductivity, and may be thermally connected to the first resistor and the ground layer. According to another aspect of the present invention, the semiconductor device may further include a second resistor disposed on the semiconductor layer, and second temperature measurement pads respectively disposed on both sides of the second resistor, wherein each of the second temperature measurement pads may be electrically connected to the second resistor.

According to another aspect of the present invention, the plurality of heat-insulating walls may be cavities filled with air.

According to another aspect of the present invention, the one or more transistors may include three transistors arranged in one direction, and the plurality of heat-insulating walls may be disposed on both sides of the channel region of the transistor disposed at a center among the three transistors to be spaced apart from the channel region.

According to another aspect of the present invention, the one or more transistors may include a plurality of transistors arranged in one direction, and the plurality of heat-insulating walls may be disposed on both sides of each channel region of the plurality of transistors to be spaced apart from the channel region.

According to another aspect of the present invention, the semiconductor device may further include two or more transistor units each including the one or more transistors, wherein at least one of the plurality of heat-insulating walls may be disposed between the two or more transistor units.

### BRIEF DESCRIPTION OF THE DRAWINGS

The above and other objects, features, and advantages of the present invention will become more apparent to those of ordinary skill in the art by describing exemplary embodiments thereof in detail with reference to the accompanying drawings, in which:

FIG. 1 is a top view of a semiconductor device according to one embodiment of the present disclosure;

FIG. 2 is a cross-sectional view of the semiconductor device of FIG. 1 taken along line II-II';

FIG. 3 is a cross-sectional view of the semiconductor device of FIG. 1 taken along line III-III';

FIG. 4 is a top view of a semiconductor device according to another embodiment of the present disclosure; and

FIG. 5 is a top view of a semiconductor device according to still another embodiment of the present disclosure.

### DETAILED DESCRIPTION OF EXEMPLARY EMBODIMENTS

Advantages and features of the present invention and implementation methods thereof will be clarified through the following embodiments described with reference to the accompanying drawings. However, the present invention is not limited to the embodiments described below and may be embodied with a variety of different modifications. The embodiments are merely provided to allow those skilled in the art to completely understand the scope of the present invention, and the present invention is defined only by the scope of the claims.

The figures, dimensions, ratios, angles, numbers, and the like disclosed in the drawings for describing the embodiments of the present invention are merely illustrative and are not limited to matters shown in the present invention. Further, in describing the present invention, detailed descriptions of well-known technologies will be omitted when it is determined that they may unnecessarily obscure the gist of the present invention. Terms such as "including," "having," and "composed of' used herein are intended to allow other elements to be added unless the terms are used with the term "only." Any references to the singular may include the plural unless expressly stated otherwise.

Components are interpreted to include an ordinary error range even if not expressly stated.

Although the terms "first," "second," and the like may be used herein to describe various components, the components are not limited by the terms. These terms are used only to distinguish one component from another component. Therefore, a first component described below may be a second component within the technological scope of the present invention.

Unless otherwise indicated herein, throughout the specification, like reference numerals refer to like elements.

Features of various embodiments of the present invention may be partially or overall coupled to or combined with each other, and may be variously inter-operated with each other and driven technically as those skilled in the art can sufficiently understand. The embodiments of the present invention may be implemented independently from each other, or may be implemented together in co-dependent relationship.

Hereinafter, the present invention will be described in detail with reference to the accompanying drawings.

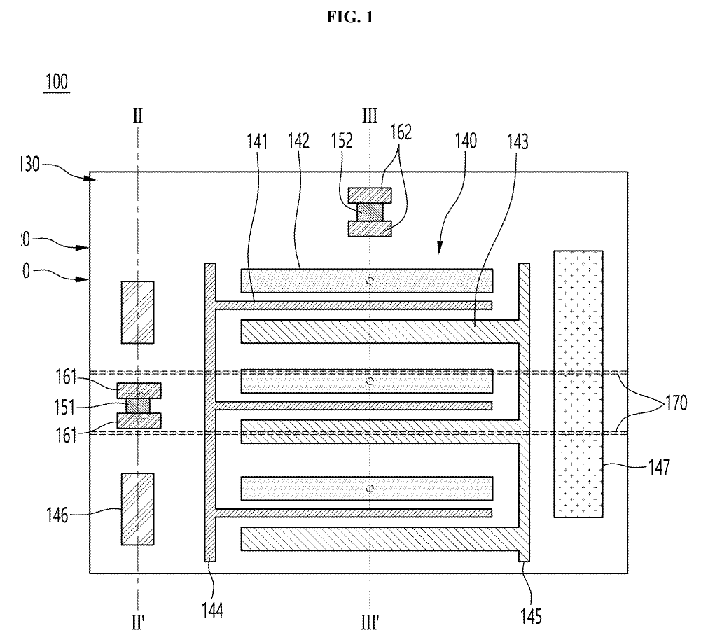

FIG. 1 is a top view of a semiconductor device according to one embodiment of the present disclosure.

Referring to FIG. 1, a semiconductor device 100 includes a semiconductor substrate 110, a semiconductor layer 120, an insulating layer 130, a gate electrode 141, a source electrode 142, a drain electrode 143, a gate line 144, a drain line 145, a first resistor 151, a first temperature measurement pad 161, and a heat-insulating wall 170. In some cases, the semiconductor device 100 may further include a gate pad 146, a drain pad 147, a second resistor 152, and a second temperature measurement pad 162.

The semiconductor device 100 is a device that controls or processes electrical signals.

Specifically, the semiconductor device 100 may be a semiconductor device used for processing high-frequency or high-power signals. For example, the semiconductor device 100 may be a radio frequency (RF) semiconductor or a power semiconductor used to transmit, receive, or transfer high-frequency or high-power signals in fields such as 5G/6G communication, satellite and radar systems, RF power amplifiers, or power conversion systems. The semiconductor substrate 110 may include various materials according to the type and required characteristics of the semiconductor device 100. Specifically, the semiconductor substrate 110 may include various materials according to the lattice constant, thermal conductivity, or coefficient of thermal expansion of the semiconductor layer 120 of the semiconductor device 100. In addition, the semiconductor substrate 110 may include various materials depending on the manufacturing process, cost, and suitability for mass production of the semiconductor device 100. For example, the semiconductor substrate 110 may include Si, SiC, A120₃, GaAs, GaN, InP, InAs, or InSb.

The semiconductor layer 120 is disposed on at least a portion of an upper part of the semiconductor substrate 110. Specifically, the semiconductor layer 120 may be disposed on only a portion of the upper part of the semiconductor substrate 110 or over an entire surface thereof. According to various embodiments of the present invention, a portion of a doped semiconductor substrate 110 may serve as the semiconductor layer 120 and a channel region (not shown) of a transistor 140. In the present embodiment, a case in which the semiconductor layer 120 is disposed over the entire surface of the upper part of the semiconductor substrate 110 will be described as an example.

The semiconductor layer 120 includes a semiconductor material. Specifically, the semiconductor layer 120 may include a compound semiconductor. For example, the semiconductor layer 120 may include GaN, AlGaN, or GaAs. According to various embodiments of the present invention, the semiconductor layer 120 may include a plurality of semiconductor materials that form a heterojunction. For example, the semiconductor layer 120 may include a semiconductor in which a plurality of semiconductor materials having different energy band gaps, such as GaN and AlGaN, form a heterojunction. Accordingly, by arranging a two-dimensional electron gas (2DEG) between GaN and AlGaN of the semiconductor layer 120, the semiconductor layer 120 may include a channel region of a GaN high electron mobility transistor (HEMT).

The insulating layer 130 may be disposed on at least a partial region of an upper surface of the semiconductor layer 120. For example, the insulating layer 130 may be disposed over the entire upper surface of the semiconductor layer 120. According to various embodiments of the present invention, the insulating layer 130 may be disposed only in a lower region of the gate electrode 141 and in an upper region of the semiconductor layer 120. That is, the insulating layer 130 may be a gate insulating layer disposed between the semiconductor layer 120 and the gate electrode 141.

The insulating layer 130 may include various insulating materials. For example, the insulating layer 130 may include silicon oxide (SiO2), silicon nitride (Si3N₄), silicon oxynitride (SixOyNz), aluminum oxide (Al203), and hafnium oxide (HfO2).

At least one transistor 140 is disposed on the semiconductor layer 120. Although a plurality of transistors 140 are illustrated in FIG. 1, the number of transistors 140 is not limited thereto. For example, the semiconductor device 100 may include only one transistor 140, or may include at least one transistor array in which a plurality of transistors 140 are arrayed.

The transistor 140 may be of various types. For example, the transistor 140 may be an HEMT, a junction field effect transistor (JFET), a metal-oxide semiconductor field effect transistor (MOSFET), or a GaN FET. In particular, the transistor 140 may be configured as a GaN FET or GaN HEMT, thereby providing high-speed switching performance and high current density. Accordingly, the semiconductor device 100 may exhibit excellent performance in power amplification and high-frequency applications.

The transistor 140 includes the gate electrode 141, the source electrode 142, the drain electrode 143, and the channel region (not shown). The channel region (not shown) of the transistor 140 is a conductive path between the source electrode 142 and the drain electrode 143, the conductivity of which is determined according to a voltage of the gate electrode 141. In the channel region of the transistor 140, a large amount of heat may be generated due to current flow and switching of the transistor 140. In particular, when the transistor 140 operates at high power and high frequency, heat generated in the channel region due to the switching operation of the transistor 140 may further increase. Accordingly, when the transistor 140 operates, the portion having the highest temperature in the semiconductor device 100 may be the channel region.

The channel region of the transistor 140 may be disposed or formed in a partial region of the semiconductor layer 120. Specifically, the channel region of the transistor 140 may be disposed or formed between the source electrode 142 and the drain electrode 143 within the semiconductor layer 120. Accordingly, the heat generated in the channel region of the transistor 140 may be conducted through the semiconductor layer 120. In particular, when the semiconductor layer 120 and the channel region include a material having high thermal conductivity, such as GaN, the heat generated in the channel region may be conducted through the semiconductor layer 120.

The gate electrode 141, the source electrode 142, and the drain electrode 143 may be disposed on the semiconductor layer 120. Specifically, the gate electrode 141 may be disposed on an upper surface of the insulating layer 130, and the source electrode 142 and the drain electrode 143 may be disposed on the semiconductor layer 120 or on the insulating layer 130. For example, the source electrode 142 and the drain electrode 143 may be disposed on the upper surface of the insulating layer 130 and connected to the semiconductor layer 120 through contact holes.

Referring to FIG. 1, the source electrode 142 and the drain electrode 143 may be spaced apart from each other with the gate electrode 141 interposed therebetween. That is, each transistor 140 may have a form in which the source electrode 142 and the drain electrode 143 are disposed to be spaced apart from each other, and the gate electrode 141 is disposed between the source electrode 142 and the drain electrode 143.

The gate line 144 and the drain line 145 may be disposed in a direction perpendicular to a direction in which the electrodes of each transistor 140 extend. The gate line 144 may be electrically connected to at least one gate electrode 141, and the drain line 145 may be electrically connected to at least one drain electrode 143.

The gate pad 146 and the drain pad 147 may be disposed spaced apart from the transistor 140 on the insulating layer 130. Specifically, the gate pad 146 and the drain pad 147 may be respectively disposed at a left edge or a right edge of the semiconductor device 100.

The gate electrode 141 and the gate line 144 may be electrically connected to the gate pad 146, and the drain electrode 143 and the drain line 145 may be electrically connected to the drain pad 147. Accordingly, the gate electrode 141 may receive a gate control signal through the gate line 144 and the gate pad 146, and the drain electrode 143 may receive or transmit an electrical signal through the drain line 145 and the drain pad 147.

Referring to FIG. 1, the semiconductor device 100 includes at least one first resistor 151. In some cases, the semiconductor device 100 may include a plurality of first resistors 151. In the present embodiment, as illustrated in FIG. 1, a case in which one first resistor 151 is disposed will be described as an example.

The first resistor 151 may be a resistor whose resistance value changes according to a temperature change. Accordingly, based on the change in the resistance value of the first resistor 151, a temperature change of the semiconductor device 100 may be monitored.

The first resistor 151 may include a material whose electrical properties change according to temperature. Specifically, the first resistor 151 may include a material having a high temperature coefficient of resistivity (TCR). For example, the first resistor 151 may include a polymer or ceramic-based material of a positive temperature coefficient (PTC) thermistor, a metal oxide material of a negative temperature coefficient (NTC) thermistor, or a GaN material. Since the first resistor 151 includes a material having a high temperature coefficient of resistivity, the temperature of the first resistor 151 may be measured more accurately based on the resistance value of the first resistor 151.

The first resistor 151 may have various shapes. For example, the first resistor 151 may have a thin-film shape formed through a deposition process or a protruding shape, that is, a mesa shape, formed through an etching process. Preferably, the first resistor 151 may be a mesa resistor whose shape and size are precisely controlled through a semiconductor process. Accordingly, as the first resistor 151 is formed using an existing semiconductor manufacturing process, manufacturing costs may be reduced.

The first resistor 151 is disposed on the semiconductor substrate 110. Specifically, the first resistor 151 may be disposed in a partial region of the semiconductor layer 120. More specifically, the first resistor 151 may be inserted into a partial region of the semiconductor layer 120 and disposed therein. Accordingly, the first resistor 151 may effectively receive heat from the semiconductor layer 120. Thus, based on the temperature of the first resistor 151 disposed in the semiconductor layer 120, the temperature of the semiconductor layer 120 and the channel region of the transistor 140 can be calculated more accurately.

Referring to FIG. 1, the first resistor 151 is illustrated as being disposed on a left side of the transistor 140, but, the position of the first resistor 151 is not limited thereto. On a plane of the semiconductor substrate 110, the first resistor 151 may be disposed on the upper side, lower side, left side, or right side of the transistor 140. That is, the first resistor 151 may be disposed in an empty space outside the transistor 140 in the semiconductor device 100.

The first resistor 151 may be disposed around the transistor 140. Specifically, the first resistor 151 may be disposed adjacent to the channel region of the transistor 140. For example, as illustrated in FIG. 1, the first resistor 151 may be disposed on an extension line of the channel region in a longitudinal direction. Accordingly, the first resistor 151 may exhibit a temperature similar to that of the channel region, which is the highest heat-generating point of the semiconductor device 100.

Referring to FIG. 1, when a plurality of transistors 140 are arranged, the first resistor 151 may be disposed adjacent to the transistor 140 located at a central portion among the plurality of transistors 140. Specifically, the first resistor 151 may be disposed adjacent to the channel region of the transistor 140 located at the center among the plurality of transistors 140. In the case of a transistor array in which the plurality of transistors 140 are arranged, the channel region of the transistor located at the center of the transistor array may have the highest temperature. That is, by being disposed adjacent to the channel region of the transistor 140 having the highest temperature among the plurality of transistors 140, the first resistor 151 may exhibit a temperature similar to the highest heat-generating point of the semiconductor device 100. Accordingly, the temperature of the highest heat-generating point of the semiconductor device 100 may be accurately calculated through the first resistor 151.

Referring to FIG. 1, the semiconductor device 100 may further include at least one second resistor 152. In some cases, the semiconductor device 100 may include a plurality of second resistors 152. In the present embodiment, as illustrated in FIG. 1, a case in which one second resistor 152 is disposed will be described as an example.

The second resistor 152 may be a resistor whose resistance value changes according to a temperature change. Accordingly, based on the change in the resistance value of the second resistor 152, a temperature change of the semiconductor device 100 may be monitored.

The second resistor 152 may have various materials and shapes. Preferably, the second resistor 152 may have substantially the same material and shape as the first resistor 151. Accordingly, the second resistor 152 may have the same electrical characteristics as the first resistor 151. Specifically, the second resistor 152 may have the same temperature coefficient of resistivity as the first resistor 151.

The second resistor 152 is disposed on the semiconductor substrate 110. Specifically, the second resistor 152 may be disposed on the upper surface of the semiconductor layer 120, on the upper surface of the insulating layer 130, or on an upper surface of another insulating layer (not shown) located on the insulating layer 130.

Referring to FIG. 1, the second resistor 152 is disposed on another side of the transistor 140 spaced apart from one side of the transistor 140 on which the first resistor 151 is disposed. For example, the first resistor 151 may be disposed on a left side of the transistor 140, and the second resistor 152 may be disposed on an upper side of the transistor 140. By being disposed on another side of the transistor 140 spaced apart from the first resistor 151, the second resistor 152 may measure a temperature other than the temperature of the channel region of the transistor 140 that the first resistor 151 may measure. For example, a temperature of the entire package, a temperature of an outer surface of the semiconductor device 100, or a temperature of air outside the semiconductor device 100 may be calculated through the second resistor 152.

By measuring the temperature of each of the first resistor 151 and the second resistor 152, not only a minute temperature change in a desired part of the semiconductor device 100 can be calculated, but also a temperature deviation of the semiconductor device 100 can be measured in real time. Accordingly, by monitoring temperatures from the highest heat- generating point of the semiconductor device 100 to air outside the semiconductor device 100, the heat dissipation state of the semiconductor device 100 and the temperature circulation inside the semiconductor device 100 may be more effectively monitored and managed.

Referring to FIG. 1, the semiconductor device 100 includes at least one first temperature measurement pad 161. Specifically, the semiconductor device 100 may include a number of first temperature measurement pads 161 that is greater than or equal to the number of first resistors 151. In the present embodiment, as illustrated in FIG. 1, a case in which two first temperature measurement pads 161 are disposed will be described as an example.

The first temperature measurement pad 161 includes a conductive material. Specifically, the first temperature measurement pad 161 may include a material having high electrical conductivity, such as a metal. In addition, the first temperature measurement pad 161 may include a material having low thermal conductivity. Specifically, the thermal conductivity of the first temperature measurement pad 161 may be lower than that of the semiconductor layer 120.

The first temperature measurement pads 161 may be electrically connected to the first resistor 151. For example, two first temperature measurement pads 161 may be respectively connected to both terminals of the first resistor 151. Accordingly, a temperature calculation module (not shown) outside the semiconductor device 100 may be electrically connected to the first temperature measurement pads 161 and may apply a current to the first resistor 151, thereby measuring the resistance value of the first resistor 151 and calculating a temperature of the first resistor 151 through the change in the resistance value.

The first temperature measurement pads 161 are disposed above the semiconductor layer 120. Specifically, each of the first temperature measurement pads 161 may be disposed to overlap an upper portion of a partial region of the first resistor 151. That is, each of the first temperature measurement pads 161 may be disposed to overlap an upper portion of a partial region of the first resistor 151 and an upper portion of a partial region of the insulating layer 130. Accordingly, as illustrated in FIG. 1, by directly arranging the first temperature measurement pads 161 above the first resistor 151, wiring for connecting the first temperature measurement pads 161 to the first resistor 151 may be omitted, thereby reducing manufacturing costs and a die size of the semiconductor device 100.

The insulating layer 130 may be disposed between the first temperature measurement pads 161 and above the first resistor 151. Specifically, the insulating layer 130 and the first temperature measurement pads 161 may be disposed to cover the entire upper surface of the first resistor 151. Accordingly, the first resistor 151 is completely isolated from external air by the insulating layer 130 and the first temperature measurement pads 161 and is prevented from spreading heat to the first temperature measurement pads 161, thereby being more closely affected by a temperature change of the semiconductor layer 120. Thus, the insulating layer 130 and the first temperature measurement pads 161 may suppress heat transferred to the first resistor 151 from being released upward, and the first resistor 151 may accurately represent the temperature of the semiconductor layer 120 and the channel region of the transistor 140. Thus, the temperature of the highest heat-generating source in the semiconductor layer 120 and the semiconductor device 100 may be more accurately measured through the temperature of the first resistor 151.

Referring to FIG. 1, the semiconductor device 100 may further include at least one second temperature measurement pad 162. Specifically, the semiconductor device 100 may include a number of second temperature measurement pads 162 that is greater than or equal to the number of second resistors 152. In the present embodiment, as illustrated in FIG. 1, a case in which two second temperature measurement pads 162 are disposed will be described as an example.

The second temperature measurement pad 162 may include various conductive materials. Preferably, the second temperature measurement pad 162 may be formed of substantially the same material as the first temperature measurement pad 161. Accordingly, the first temperature measurement pad 161 and the second temperature measurement pad 162 may have the same electrical characteristics.

The second temperature measurement pads 162 are disposed above the semiconductor substrate 110. Specifically, the second temperature measurement pads 162 may be disposed on the upper surface of the semiconductor layer 120, on the upper surface of the insulating layer 130, or on the upper surface of another insulating layer (not shown) located on the insulating layer 130. For example, the second temperature measurement pads 162 may be disposed in the same layer as the second resistor 152 disposed on the upper surface of the insulating layer 130.

Referring to FIG. 1, two second temperature measurement pads 162 may be disposed on both sides of the second resistor 152. Specifically, two second temperature measurement pads 162 may be disposed in direct contact with both terminals of the second resistor 152. Accordingly, two second temperature measurement pads 162 may be electrically connected to both terminals of the second resistor 152. Thus, a temperature calculation module (not shown) may be electrically connected to the second temperature measurement pads 162 and may apply a current to the second resistor 152, thereby calculating a temperature of the second resistor 152.

Referring to FIG. 1, the semiconductor device 100 includes at least one heat-insulating wall 170. Preferably, the semiconductor device 100 may include a plurality of heat-insulating walls 170.

The heat-insulating walls 170 may extend in one direction. Specifically, the heat- insulating walls 170 may extend in a longitudinal direction of the gate electrode 141. That is, as illustrated in FIG. 1, the heat-insulating walls 170 may extend in a longitudinal direction of the channel region of the transistor 140. More specifically, the heat-insulating walls 170 may pass through the semiconductor device 100 in the longitudinal direction of the channel region of the transistor 140. According to various embodiments of the present invention, the heat- insulating walls 170 may extend from a region in which the first resistor 151 is disposed only to a region in which the transistor 140 is disposed.

The heat-insulating wall 170 may include various materials. Specifically, the heat- insulating wall 170 may include a material having low thermal conductivity. For example, the heat-insulating wall 170 may include an insulating material including silicon oxide, silicon nitride, an air gap, polyimide, aluminum oxide, and an organic insulating material, or a conductive material including doped polysilicon, graphene, a metal-dielectric composite material, a conductive polymer, stainless steel, Invar, a thin-film metal, and a nanostructured metal. According to various embodiments of the present invention, the heat-insulating wall 170 may also include a material having high thermal conductivity. For example, the heat- insulating wall 170 may include a metal material such as copper or aluminum. The heat- insulating wall 170 may provide a heat insulating effect by inducing heat transfer only to a specific region or rapidly dispersing heat to the specific region through a thermally conductive metal material.

The heat-insulating wall 170 may have various shapes. Specifically, the heat- insulating wall 170 may have a wall shape extending in one direction. For example, the heat- insulating wall 170 may have the shape of a wall formed in a groove extending in one direction in the semiconductor substrate 110 or the semiconductor layer 120. That is, the heat- insulating wall 170 may be vertically disposed and may have a plate shape extending in one direction. According to various embodiments of the present invention, the heat-insulating wall 170 may have a shape in which a plurality of vias are arranged. For example, the heat- insulating wall 170 may have a shape in which a plurality of vias arranged in one direction are connected to each other to form a wall. Accordingly, the heat-insulating wall 170 may block heat transfer between materials on both sides separated by the heat-insulating wall 170. Thatis, the heat-insulating wall 170 may block heat transfer between portions of the semiconductor layer 120 separated by the heat-insulating wall 170, and may block heat transfer between portions of the semiconductor substrate 110 separated by the heat-insulating wall 170. In some cases, the heat-insulating wall 170 may have a shape in which a plurality of spaced-apart vias are disposed adjacent to each other. When the heat-insulating wall 170 has a shape in which a plurality of spaced-apart vias are disposed adjacent to each other, the heat-insulating wall 170 may provide a heat insulating effect by reducing a heat transfer path of the semiconductor layer 120, and may also provide a heat insulating effect by inducing heat transfer to a lower region of the semiconductor layer 120.

The heat-insulating walls 170 may be disposed spaced apart from the channel region of the transistor 140. Specifically, the heat-insulating walls 170 may be disposed on both sides of the channel region of the transistor 140 to be spaced apart from the channel region, with the channel region interposed therebetween. More specifically, as illustrated in FIG. 1, the heat- insulating walls 170 may be disposed below each of the source electrode 142 and the drain electrode 143 to be spaced apart from the channel region of the transistor 140. In some cases, the heat-insulating walls 170 may be disposed on both sides of the transistor 140 to be spaced apart from the transistor 140, with the source electrode 142 and the drain electrode 143 interposed therebetween. The channel region of the transistor 140 is a path through which a current flows between the source electrode 142 and the drain electrode 143 and which is controlled by a voltage of the gate electrode 141. Accordingly, when the heat-insulating wall 170 having conductive properties is disposed in the channel region of the transistor 140, leakage current may increase and an electrical short circuit may occur. In addition, when the heat-insulating wall 170 having insulating properties is disposed in the channel region of the transistor 140, the heat-insulating wall 170 may break the continuity of the channel, thereby hindering channel formation, and may cause problems such as reduced charge mobility and formation of parasitic electric field. Thus, the heat-insulating wall 170 according to the present embodiment may be disposed in a depletion region or neutral region of the semiconductor layer 120. As a result, a problem in which the electrical characteristics of the channel region are reduced or the formation of the channel region is hindered due to the position or configuration of the heat-insulating wall 170 can be prevented.

Referring to FIG. 1, the heat-insulating walls 170 may be disposed on both sides of the channel region of the transistor 140 located at the center among the plurality of transistors 140. That is, the heat-insulating walls 170 may be disposed on both sides of a region having the highest temperature in the transistor array in which the plurality of transistors 140 are arranged. Accordingly, by insulating both sides of the channel region of the transistor 140 having the highest temperature among the plurality of transistors 140, the heat-insulating walls 170 may prevent mutual heating between the channel regions. Thus, the heat-insulating walls 170 may prevent overheating of the highest heat-generating source of the semiconductor device 100 and may maintain the temperature of the highest heat-generating source more stably. Accordingly, since a degree of heat generation in the channel region caused by operation of the transistor 140 is accurately monitored, a degree of degradation of the transistor 140 may be calculated based on the degree of heat generation.

The first resistor 151 may be disposed between the heat-insulating walls 170. That is, as illustrated in FIG. 1, the first resistor 151 may be disposed between the heat-insulating walls 170 together with the channel region of the transistor 140. Heat generated in the channel region disposed between the heat-insulating walls 170 may be more completely transferred to the first resistor 151 disposed between the heat-insulating walls 170. Accordingly, the first resistor 151 disposed between the heat-insulating walls 170 may have a temperature more similar to that of the channel region of the transistor 140 disposed between the heat-insulating walls 170.

The semiconductor device 100 according to the present embodiment may prevent mutual heating between the channel regions by including the heat-insulating walls 170 disposed on both sides of the channel region of the transistor 140. Accordingly, the semiconductor device 100 may prevent overheating of the channel region by including the heat-insulating walls 170 that block thermal interaction between the channel region and the operation of the corresponding transistor 140. adjacent regions. Thus, the channel region of the transistor 140 disposed between the heat- insulating walls 170 may more completely preserve the degree of heat generation caused by the operation of the corresponding transistor 140.

The semiconductor device 100 according to the present embodiment may more accurately measure the degree of heat generation of the channel region caused by the operation of the transistor 140 by including the channel region of the transistor 140 and the first resistor 151 that are disposed between the heat-insulating walls 170. Accordingly, as the degree of heat generation of the channel region caused by the operation of the transistor 140 disposed between the heat-insulating walls 170 is precisely monitored, the degree of degradation of the corresponding transistor 140 may be calculated more accurately.

The semiconductor device 100 according to the present embodiment may accurately measure the temperature of the highest heat-generating source of the semiconductor device 100 by including the heat-insulating walls 170 that are disposed on both sides of the channel region of the transistor 140 located at the center among the plurality of transistors 140 and the first resistor 151. Accordingly, the semiconductor device 100 may quickly and accurately perform heat dissipation operation and heat generation management response based on the accurate temperature of the highest heat-generating channel region. Thus, since a response according to the temperature of the highest heat-generating point of the semiconductor device 100 is quickly made, the degradation rate and performance degradation of semiconductor elements disposed in the semiconductor device 100 may be reduced, and the lifespan thereof may be extended.

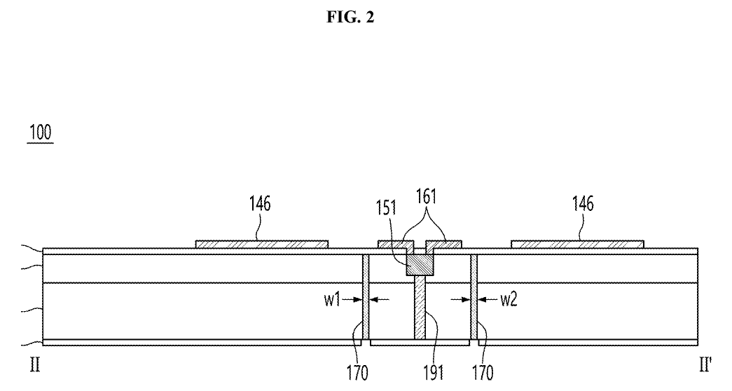

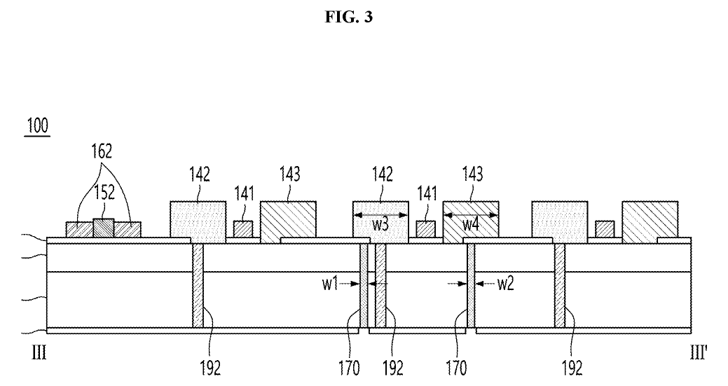

FIG. 2 is a cross-sectional view of the semiconductor device of FIG. 1 taken along line II-II'. FIG. 3 is a cross-sectional view of the semiconductor device of FIG. 1 taken along line III-III'.

Referring to FIGS. 2 and 3, the semiconductor device 100 further includes a ground layer 180 disposed below the semiconductor substrate 110. In some cases, the semiconductor device 100 may further include a first via 191 and a second via 192.

As described above, the first resistor 151 may be disposed in a partial region of the semiconductor layer 120. For example, as shown in FIG. 2, the first resistor 151 may be disposed by being inserted to an intermediate depth of the semiconductor layer 120. In some cases, the first resistor 151 may be disposed to pass through the semiconductor layer 120. The first resistor 151 may be formed to be disposed inside the semiconductor layer 120 in a process of forming the semiconductor layer 120, thereby reducing additional processes required for disposing the first resistor 151 in the semiconductor device 100 and accordingly reducing costs.

Referring to FIG. 2, the heat-insulating walls 170 may be disposed between a lower surface of the semiconductor substrate 110 and the upper surface of the semiconductor layer 120. Specifically, the heat-insulating walls 170 may be disposed to pass through the semiconductor layer 120 between the lower surface of the semiconductor substrate 110 and the upper surface of the semiconductor layer 120. For example, when the heat-insulating walls 170 are cavities filled with air, the heat-insulating walls 170 may be disposed to pass through the semiconductor layer 120 between the upper surface of the semiconductor layer 120 and a lower surface of the semiconductor layer 120. When the heat-insulating walls 170, which are cavities filled with air, pass through both the semiconductor layer 120 and the semiconductor substrate 110, cracks may occur in the semiconductor device 100 or durability may be reduced. Accordingly, by arranging the heat-insulating walls 170, which are cavities filled with air, to pass through only the semiconductor layer 120, the durability of the semiconductor device 100 may be ensured while efficiently insulating the semiconductor layer 120. In some cases, as illustrated in FIGS. 2 and 3, the heat-insulating walls 170 may be disposed to vertically pass through the semiconductor substrate 110 and the semiconductor layer 120. By being disposed to pass through the semiconductor layer 120, the heat-insulating walls 170 may block heat transfer between portions of the semiconductor layer 120 separated by the heat-insulating walls 170. Further, by being disposed to pass through both the semiconductor substrate 110 and the semiconductor layer 120, the heat-insulating walls 170 may more effectively block heat transfer between portions of the semiconductor layer 120 separated by the heat-insulating walls 170.

Referring to FIGS. 2 and 3, the heat-insulating walls 170 may be disposed in contact with a lower surface of the insulating layer 130. For example, the heat-insulating walls 170 may be disposed in contact with the lower surface of the insulating layer 130 disposed below the source electrode 142, the drain electrode 143, the gate line 144, the drain line 145, the gate pad 146, the drain pad 147, the second resistor 152, the first temperature measurement pad 161, or the second temperature measurement pad 162. Accordingly, the heat-insulating walls 170 may thermally insulate the semiconductor layer 120 without reducing integration density of the semiconductor device 100. In addition, by being disposed in contact with the lower surface of the insulating layer 130, the heat-insulating walls 170 may prevent leakage current and electrical short circuit problems even when the heat-insulating wall 170 includes a conductive material.

According to various embodiments of the present invention, when the heat-insulating wall 170 includes an insulating material, the heat-insulating wall 170 may be disposed in direct contact with a lower surface of each of the source electrode 142, the drain electrode 143, the gate line 144, the drain line 145, the gate pad 146, the drain pad 147, the second resistor 152, the first temperature measurement pad 161, or the second temperature measurement pad 162. That is, the heat-insulating wall 170 may be disposed to pass through the insulating layer 130, or may be disposed in a region in which the insulating layer 130 is not formed. For example, when the heat-insulating walls 170 are cavities filled with air, the heat-insulating wall 170 may be disposed in contact with the lower surfaces of the source electrode 142 and the drain, or electrode 143 that are directly disposed on the upper surface of the semiconductor layer 120. Accordingly, by including the heat-insulating walls 170 that are cavities filled with air, the semiconductor device 100 may secure stable contact resistance and current transfer efficiency of the source electrode 142 and the drain electrode 143, while blocking thermal interaction between the channel regions.

Referring to FIG. 3, the heat-insulating walls 170 may be disposed on both sides of the channel region of the transistor 140 to be spaced apart from the channel region of the transistor 140. Specifically, the heat-insulating walls 170 may be disposed below the source electrode 142 and the drain electrode 143 to be spaced apart from the channel region. That is, the heat- insulating walls 170 may be disposed in a depletion region or neutral region of the semiconductor layer 120 below the source electrode 142 and the drain electrode 143. For example, each of the heat-insulating walls 170 may be disposed between the center of the lower surface of the source electrode 142 or the drain electrode 143, and an outer edge of the transistor 140. That is, as illustrated in FIG. 3, the heat-insulating walls 170 may be disposed respectively in a left-side region of the second via 192 located below the source electrode 142, and in a region between the center and a right edge of the lower surface of the drain electrode 143. Accordingly, by being disposed below the source electrode 142 and the drain electrode 143 of the transistor 140, the heat-insulating walls 170 may thermally insulate the semiconductor layer 120 without reducing the integration density of the transistor 140. Thus, even in a miniaturized and highly integrated semiconductor device 100, the heat-insulating walls 170 can block mutual heating between the channel regions of the respective transistors 140 disposed adjacent to each other, thereby preventing overheating of the channel regions and enabling accurate measurement and management of the amount of heat generation.

A width of the heat-insulating wall 170 may vary depending on a material included in the heat-insulating wall 170 and a position at which the heat-insulating wall 170 is disposed. Specifically, the heat-insulating walls 170 disposed at different positions may have different widths. More specifically, a width wl of the heat-insulating wall 170 disposed below the source electrode 142 may be different from a width w2 of the heat-insulating wall 170 disposed below the drain electrode 143. That is, the width wl of the heat-insulating wall 170 disposed below the source electrode 142 may be smaller than the width w2 of the heat-insulating wall 170 disposed below the drain electrode 143. Accordingly, the heat-insulating wall 170 can be spaced a predetermined distance or more apart from the second via 192, thereby providing sufficient heat insulating effects while minimizing effects on electrical characteristics of the transistor 140.

Referring to FIGS. 2 and 3, the ground layer 180 may be disposed on at least a partial region of a lower portion of the semiconductor substrate 110. For example, the ground layer 180 may be disposed only in lower regions of the transistor 140 and the first resistor 151. In the present embodiment, a case in which the ground layer 180 is disposed over the entire lower surface of the semiconductor substrate 110 will be described as an example.

The ground layer 180 includes a conductive material. For example, the ground layer 180 may include a metal having high electrical conductivity. In addition, the ground layer 180 may include a material having high thermal conductivity. Accordingly, heat generated in the channel region of the transistor 140 may be transferred to the ground layer 180 through the semiconductor layer 120 and the semiconductor substrate 110 to be released to the outside.

The ground layer 180 may be grounded. In this case, the ground layer 180 may serve as a ground electrode of the transistor 140.

The ground layer 180 may include at least one ground pattern. Specifically, as illustrated in FIGS. 2 and 3, the ground layer 180 may include a plurality of ground patterns spaced apart from each other. The plurality of ground patterns may be disposed spaced apart from each other in a region in which the heat-insulating wall 170 is located. That is, in a planar direction of the semiconductor substrate 110, the heat-insulating wall 170 and the ground patterns of the ground layer 180 may not overlap each other. Accordingly, the plurality of ground patterns may be thermally separated from each other in the region in which the heat-insulating wall 170 is located. Thus, the channel region of the transistor 140, which is thermally insulated by the heat-insulating walls 170, may be prevented from thermally interacting not only with the semiconductor layer 120 and the semiconductor substrate 110, but also with the ground layer 180. That is, as illustrated in FIGS. 2 and 3, by including the ground layers 180 spaced apart from each other in the region in which the heat-insulating wall 170 is located, the semiconductor device 100 may more accurately measure the amount of heat generation in the channel region caused by the operation of the transistor 140 through the first resistor 151 disposed between the heat-insulating walls 170.

A separation distance between the ground patterns of the ground layer 180 may vary. Specifically, the separation distance between the ground patterns of the ground layer 180 may vary depending on the width of the heat-insulating wall 170 located at the corresponding position. Accordingly, by being completely spaced apart from the heat-insulating wall 170, the ground layer 180 may prevent signal distortion and unnecessary power consumption. In addition, each of the ground patterns of the ground layer 180 may secure a sufficient area while being thermally separated from each other, thereby minimizing deterioration of heat dissipation performance.

Referring to FIG. 2, the first via 191 may be disposed between the first resistor 151 and the ground layer 180. Specifically, the first via 191 may pass through the semiconductor substrate 110 and may be disposed between the first resistor 151 and the ground layer 180. More specifically, the first via 191 may vertically pass through the semiconductor substrate 110 to be in contact with a lower surface of the first resistor 151 and an upper surface of the ground layer 180.

The first via 191 may include a thermally conductive material. Specifically, the first via 191 may include a material having higher thermal conductivity than the semiconductor layer 120. For example, the first via 191 may include a thermally conductive metal, silicon oxide or polyimide mixed with a thermally conductive filler, epoxy, aluminum nitride (AlN), silicon carbide (SiC), beryllia (BeG), magnesium oxide (MgO), or boron nitride, which is filled in a hole. That is, the first via 191 may include a thermally conductive metal or doped silicon carbide (SiC), which are electrically conductive materials, or may include silicon oxide or polyimide mixed with a thermally conductive filler, epoxy, aluminum nitride (AlN), beryllia (BeG), magnesium oxide (MgO), or boron nitride (BN), which are insulating materials.

The first via 191 may thermally connect the first resistor 151 to the ground layer 180. Accordingly, heat energy generated in the channel region of the transistor 140 and transferred to the ground layer 180 may be conducted to the first resistor 151 through the first via 191. Thus, the first resistor 151 may receive heat generated in the channel region of the transistor 140 not only through the semiconductor layer 120 but also from the ground layer 180. As described above, since the first resistor 151 may receive heat generated in the channel region of the transistor 140 in two ways, a temperature of the first resistor 151 may become similar to that of the highest heat-generating source of the semiconductor device 100. Thus, by measuring the resistance value of the first resistor 151, the temperature of the highest heat- generating source of the semiconductor device 100 may be measured with high accuracy.

The first via 191 may not be electrically connected to the first resistor 151. For example, the first via 191 may include an insulating material having high thermal conductivity. In some cases, the first via 191 may also include an electrically conductive material. When the first via 191 includes an electrically conductive material, the first via 191 may be in contact with the insulating layer disposed on the lower surface of the first resistor 151. Specifically, both terminals of the first resistor 151 may be electrically connected to the first temperature measurement pads 161, respectively, and the first via 191 may be in contact with the surface of the first resistor 151 that is insulated, and thus the first via 191 and the first resistor 151 may not be electrically connected. Accordingly, while receiving heat from the channel region of the transistor 140 through the first via 191 without being grounded, the change in the resistance value according to temperature of the first resistor 151 may be more accurately measured through the first temperature measurement pad 161.

Referring to FIG. 3, the second via 192 may be disposed between the source electrode 142 and the ground layer 180. Specifically, the second via 192 may pass through the semiconductor substrate 110 and may be disposed between the source electrode 142 and the ground layer 180. More specifically, the second via 192 may vertically pass through the semiconductor substrate 110 to be in contact with the lower surface of the source electrode 142 and the upper surface of the ground layer 180.

The second via 192 may include an electrically conductive material. Specifically, the second via 192 may include a material having electrical conductivity and thermal conductivity. More specifically, the second via 192 may include an electrically conductive material having a thermal conductivity higher than that of the semiconductor layer 120. For example, the second via 192 may include a thermally conductive metal. The second via 192 may electrically connect the source electrode 142 to the ground layer 180. Specifically, the second via 192 may electrically and thermally connect the source electrode 142 to the ground layer 180. When the second via 192 electrically connects the source electrode 142 to the ground layer 180, the source electrode 142 may be grounded. Thus, the semiconductor device 100 may not include a source pad for applying an electrical signal to the source electrode 142. Accordingly, the semiconductor device 100 may be miniaturized by an area corresponding to an area for arranging the source pad, and more devices may be disposed in the semiconductor device 100 to enable integration. When the second via 192 thermally connects the source electrode 142 to the ground layer 180, heat generated in the semiconductor layer 120 may be transferred to the source electrode 142 and the ground layer 180 through the second via 192 and may be released to the outside.

Referring to FIGS. 2 and 3, the first via 191 and the second via 192 may thermally connect the channel region of the transistor 140 to the first resistor 151. That is, heat generated in the channel region of the transistor 140 may be transferred to the first resistor 151 through the second via 192, the ground layer 180, and the first via 191. Thus, the first resistor 151 may accurately represent the temperature of the channel region of the transistor 140. Accordingly, the temperature of the channel region of the transistor 140, which is the highest heat-generating source of the semiconductor device, may be accurately measured through the first resistor 151.

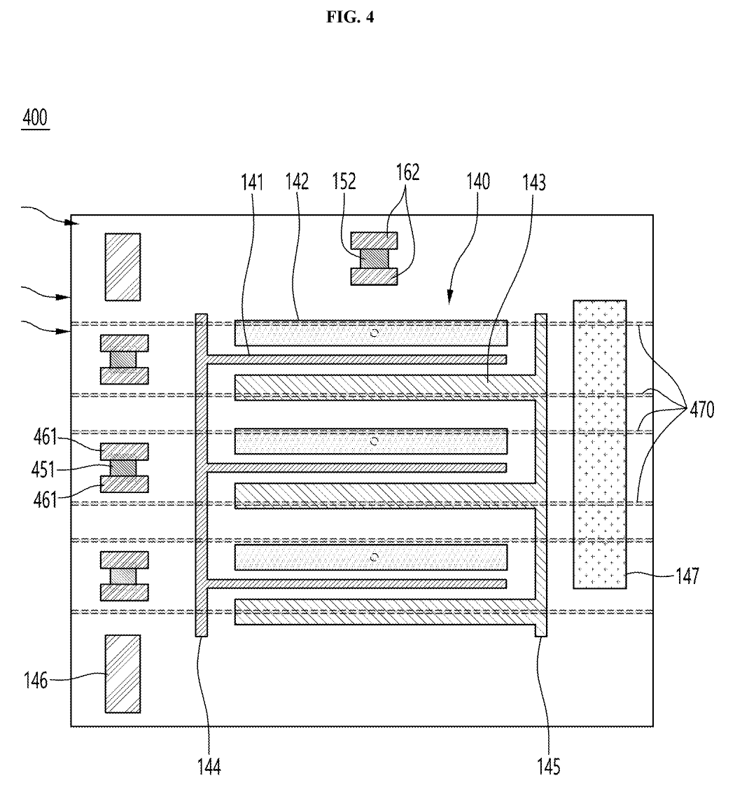

FIG. 4 is a top view of a semiconductor device according to another embodiment of the present disclosure.

Referring to FIG. 4, a semiconductor device 400 according to the present embodiment further includes heat-insulating walls 470 disposed on both sides of the channel region of each of all the transistors 140, and a first resistor 451 and first temperature measurement pads 461, which are disposed between the respective heat-insulating walls 470 together with the channel region of the transistor 140, in the configuration of the semiconductor device 100 of FIG. 1. Accordingly, redundant descriptions of substantially the same configuration as the semiconductor device 100 of FIG. 1 will be omitted.

Referring to FIG. 4, the heat-insulating walls 470 may be disposed between each channel region of the respective transistors 140. Specifically, the heat-insulating walls 470 may be disposed on both sides of the channel region of each of all the transistors 140. For example, the heat-insulating walls 470 may be disposed below the source electrode 142 and the drain electrode 143 of each of all the transistors 140. In some cases, the heat-insulating wall 470 may be disposed only below one of the source electrode 142 and the drain electrode 143 of each of the transistors 140. For example, the heat-insulating wall 470 may be disposed only below the drain electrode 143 of each of the transistors 140. Accordingly, the heat- insulating walls 470 may thermally isolate the channel regions of the respective transistors 140 while simplifying a process of forming the heat-insulating walls 470.

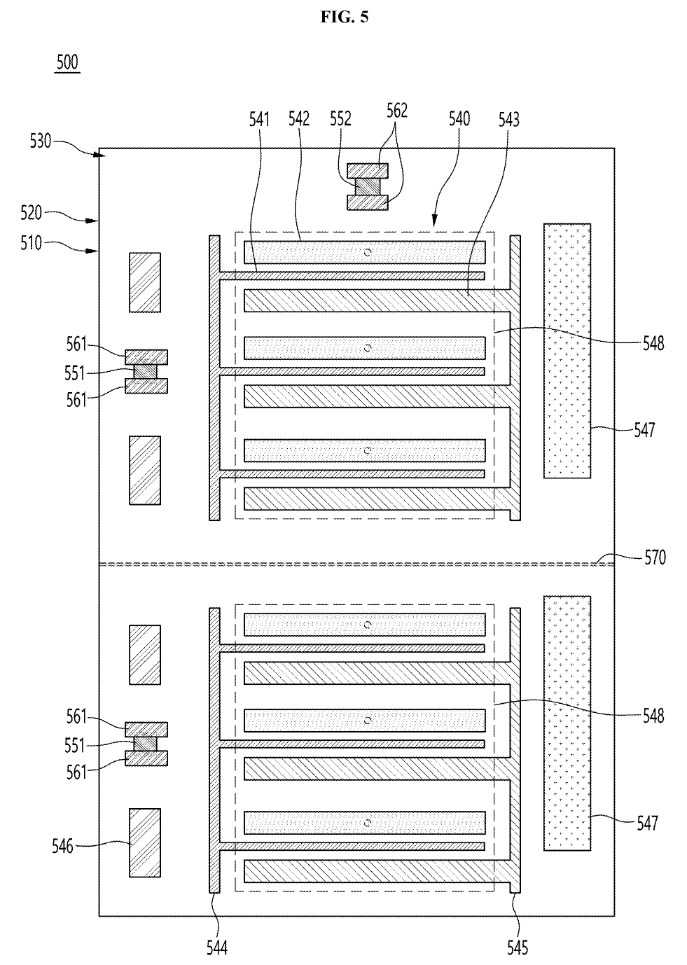

FIG. 5 is a top view of a semiconductor device according to still another embodiment of the present disclosure.

Referring to FIG. 5, a semiconductor device 500 according to the present embodiment may further include a plurality of transistor units 548 each including a plurality of transistors 540, in the configuration of the semiconductor device 100 of FIG. 1, and may be configured such that a heat-insulating wall 570 is disposed between the plurality of transistor units 548.

Accordingly, redundant descriptions of substantially the same configuration as the semiconductor device 100 of FIG. 1 will be omitted.

Referring to FIG. 5, each of the transistor units 548 includes the plurality of transistors 540. Specifically, each of the transistor units 548 may include the plurality of transistors 540 arranged in one direction.

The transistor units 548 may be spaced apart from each other. Specifically, the transistor units 548 may be spaced apart from each other by a distance greater than or equal to a distance between the plurality of transistors 540 arranged in one transistor unit 548.

The heat-insulating wall 570 may be substantially the same as the heat-insulating wall 170 of FIG. 1. Referring to FIG. 5, the heat-insulating wall 570 may be disposed between the transistor units 548. Specifically, the heat-insulating wall 570 may be disposed at the center between the transistor units 548. Accordingly, the heat-insulating wall 570 may block heat transfer between the transistor units 548.

A first resistor 551 and a first temperature measurement pad 561 may have substantially the same configuration as the first resistor 151 and the first temperature measurement pad 161 of FIG. 1. Referring to FIG. 5, the first resistor 551 and the first temperature measurement pad 561 may be disposed around each of the transistor units 548. Specifically, the first resistor 551 and the first temperature measurement pad 561 may be disposed adjacent to a channel region of the transistor 540 disposed at the center of each of the transistor units 548. Accordingly, temperatures of the highest heat-generating sources of the transistor units 548 may be measured through the first resistors 551, respectively. Accordingly, by comparing the temperatures of the highest heat-generating sources of the transistor units 548, the transistor unit 548 in which the transistor 540 having degradation or defects is disposed may be efficiently detected.

According to one of the problem-solving means of the present invention, a semiconductor device can accurately measure a degree of heat generation of a semiconductor layer and a highest heat-generating source of the semiconductor device by including a resistor disposed in the semiconductor layer.

According to one of the problem-solving means of the present invention, a semiconductor device can block heat transferred from surrounding heat-generating points by including a heat-insulating wall disposed to pass through a semiconductor layer.

According to one of the problem-solving means of the present invention, a semiconductor device can prevent mutual heating between transistors by including a heat- insulating wall disposed between the transistors and between channel regions.

According to one of the problem-solving means of the present invention, a semiconductor device can minimize the influence of ambient temperature on a target semiconductor element and a target heat-generating point by including a plurality of ground pads that receive heat of a semiconductor layer and are spaced apart from each other in a region in which a heat-insulating wall is disposed.

According to one of the problem-solving means of the present invention, a semiconductor device can more accurately measure a temperature of a target semiconductor element and a target heat-generating point by including a resistor disposed between heat- insulating walls.

According to one of the problem-solving means of the present invention, a semiconductor device can prevent degradation in performance and reduction in lifespan of the semiconductor device by accurately monitoring, in real time, temperatures of a semiconductor layer and a highest heat-generating source.

According to one of the problem-solving means of the present invention, a semiconductor device can achieve a small volume and low manufacturing cost by including a temperature measurement pad directly connected to an upper portion of a resistor.

According to one of the problem-solving means of the present invention, a semiconductor device can more accurately measure a temperature of a semiconductor layer regardless of an ambient temperature outside the device by including a resistor whose upper portion is covered with a temperature measurement pad and an insulator.

The effects obtainable from the present invention are not limited to the effects mentioned above, and other effects not mentioned will be clearly understood by those skilled in the art to which the present invention pertains from the following description.

While the embodiments of the present invention have been described in detail above with reference to the accompanying drawings, the present invention is not necessarily limited to these embodiments, and various changes and modifications may be made without departing from the technical spirit of the present invention. Accordingly, the embodiments disclosed herein are to be considered descriptive and not restrictive of the technical spirit of the present invention, and the scope of the technical spirit of the present invention is not limited by these embodiments. Accordingly, the above-described embodiments should be understood to be exemplary and not limiting in any aspect. The scope of the present invention should be construed by the appended claims along with the full range of equivalents to which such claims are entitled.

What is claimed is:

1. A semiconductor device comprising:
a ground layer;
a semiconductor substrate disposed on the ground layer;
a semiconductor layer disposed on the semiconductor substrate;
one or more first resistors disposed in the semiconductor layer;
one or more first temperature measurement pads disposed on the semiconductor layer;
one or more transistors disposed on the semiconductor layer; and
a plurality of heat-insulating walls passing through the semiconductor layer,
wherein each of the one or more transistors includes a gate electrode, a source electrode, a drain electrode, and a channel region located between the source electrode and the drain electrode in the semiconductor layer.

2. The semiconductor device of claim 1, wherein the plurality of heat-insulating walls are disposed on both sides of the channel region to be spaced apart from the channel region.

3. The semiconductor device of claim 2, wherein the one or more first resistors are disposed between the plurality of heat-insulating walls.

4. The semiconductor device of claim 3, wherein the one or more first temperature measurement pads are disposed on the one or more first resistors.

5. The semiconductor device of claim 4, further comprising an insulating layer disposed on the one or more first resistors,
wherein the insulating layer and the one or more first temperature measurement pads cover entire upper surfaces of the one or more first resistors.

6. The semiconductor device of claim 1, further comprising an insulating layer disposed between the semiconductor layer and each of the source electrode and the drain electrode,
wherein the heat-insulating walls are disposed below the insulating layer.

7. The semiconductor device of claim 6, wherein the plurality of heat-insulating walls are disposed to pass through between an upper surface of the semiconductor layer and a lower surface of the semiconductor substrate.

8. The semiconductor device of claim 1, wherein the ground layer includes a plurality of ground patterns, and
the plurality of ground patterns are spaced apart from each other in regions in which the plurality of heat-insulating walls are disposed.

9. The semiconductor device of claim 1, further comprising:
a first via disposed between the ground layer and each of the one or more first resistors;
and a second via disposed between the source electrode and the ground layer,wherein the second via has thermal conductivity and electrical conductivity and is electrically connected to the source electrode and the ground layer.

10. The semiconductor device of claim 9, wherein the first via has thermal
conductivity and is thermally connected to the first resistor and the ground layer.

11. The semiconductor device of claim 1, further comprising:
a second resistor disposed on the semiconductor layer; and
second temperature measurement pads respectively disposed on both sides of the second resistor,
wherein each of the second temperature measurement pads is electrically connected to the second resistor.

12. The semiconductor device of claim 1, wherein the plurality of heat-insulating walls are cavities filled with air.

13. The semiconductor device of claim 1, wherein the one or more transistors include three transistors arranged in one direction, and
the plurality of heat-insulating walls are disposed on both sides of the channel region of the transistor disposed at a center among the three transistors to be spaced apart from the channel region.

14. The semiconductor device of claim 1, wherein the one or more transistors include a plurality of transistors arranged in one direction, and
the plurality of heat-insulating walls are disposed on both sides of each channel region of the plurality of transistors to be spaced apart from the channel region.

15. The semiconductor device of claim 1, further comprising two or more transistor units each including the one or more transistors,
wherein at least one of the plurality of heat-insulating walls is disposed between the two or more transistor units.
